(19) United States
(12) Patent Application Publication
(10) Pub. No.: US 2017/0181276 A1
(43) Pub. Date: Jun. 22, 2017

(54) SUBSTRATE INCLUDING STRETCHABLE SHEET

(71) Applicant: Panasonic Intellectual Property Management Co., Ltd., Osaka (JP)

(72) Inventors: SUSUMU SAWADA, Osaka (JP); YOSHIHIRO TOMITA, Osaka (JP); KOICHI HIRANO, Osaka (JP); HIDEKI OHMAE, Hyogo (JP)

(21) Appl. No.: 15/370,072

(22) Filed: Dec. 6, 2016

(30) Foreign Application Priority Data
Dec. 21, 2015 (JP) 2015-248992

(51) Int. Cl. H05K 1/02; H05K 1/18; B32B 5/04; B32B 7/08; B32B 3/26; B32B 5/02

(52) U.S. Cl. CPC H05K 1/0283; B32B 3/266; B32B 5/026; B32B 5/028; B32B 5/04; B32B 7/08; H05K 1/18; B32B 2250/02; B32B 2262/0207; B32B 2307/202; B32B 2307/206; B32B 2307/51; B32B 2457/00

(57) ABSTRACT

A substrate is provided with: a stretchable sheet; a plurality of members located on the sheet; a plurality of strips that are stretchable, and that connect the plurality of members; and a plurality of fiber threads that sew the plurality of members and the sheet together.

### BACKGROUND

1. Technical Field

The present disclosure relates to a substrate including a stretchable sheet.

2. Description of the Related Art

Flexible substrates have often been used in recent years due to the miniaturization and/or thinning of electronic devices. The use of flexible substrates has been achieved in various fields besides the field of typical electronic devices. For example, flexible substrates have been used in mobile devices such as smartphones and also wearable devices.

Wearable devices are required to be able to easily attach to movable parts of a measurement subject (a human body, for example), and to be able to perform sensing in close contact with the measurement subject. Consequently, flexible substrates are required to have sufficient stretchability. A flexible substrate having a serpentine structure is known as prior art (Japanese Unexamined Patent Application Publication No. 2000-294886).

### SUMMARY

In one general aspect, the techniques disclosed here feature a substrate that is provided with: a stretchable sheet; a plurality of members located on the sheet; a plurality of strips that are stretchable, and that connect the plurality of members; and a plurality of fiber threads that sew the plurality of members and the sheet together.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a drawing schematically depicting a stretchable flexible substrate according to an embodiment;

FIG. 2A is a drawing schematically depicting an example of a stretchable flexible substrate according to an embodiment;

FIG. 2B is a drawing schematically depicting an example of a cross-sectional structure of the stretchable flexible substrate depicted in FIG. 2A;

FIG. 2C is a drawing schematically depicting an example of a stretchable flexible substrate according to an embodiment;

FIG. 3A is a drawing schematically depicting an example of a wiring layer of a stretchable flexible substrate according to an embodiment;

FIG. 3B is a drawing schematically depicting an example of a wiring layer of a stretchable flexible substrate according to an embodiment;

FIG. 4 is a schematic drawing for illustrating an example of the relationship between a wiring layer and the direction of a force applied to the wiring layer;

FIG. 5 is a drawing schematically depicting an example of a stretchable flexible substrate according to an embodiment;

FIG. 6A is a schematic drawing for illustrating the stretching behavior of a wiring layer of a stretchable flexible substrate according to an embodiment;

FIG. 6B is a schematic drawing for illustrating the stretching behavior of a wiring layer of a stretchable flexible substrate according to an embodiment;

FIG. 7A is a schematic drawing for depicting an example of a stretchable flexible substrate according to an embodiment;

FIG. 7B is a drawing schematically depicting an example of a cross-sectional structure of the stretchable flexible substrate depicted in FIG. 7A;

FIG. 7C is a drawing schematically depicting an example of a cross-sectional structure of the stretchable flexible substrate depicted in FIG. 7A;

FIG. 8A is a drawing schematically depicting a fiber knitted material having a knitted structure;

FIG. 8B is a schematic drawing for illustrating deformation of a fiber knitted material having a knitted structure;

FIG. 9A is a drawing schematically depicting a fiber knitted material having a net structure;

FIG. 9B is a schematic drawing for illustrating deformation of a fiber knitted material having a net structure;

FIG. 10A is a drawing schematically depicting a first modified example of a stretchable flexible substrate according to an embodiment;

FIG. 10B is a drawing depicting a cross-sectional structure of the stretchable flexible substrate depicted in FIG. 10A;

FIG. 10C is a drawing schematically depicting a second modified example of a stretchable flexible substrate according to an embodiment;

FIG. 10D is a drawing depicting an example of a cross-sectional structure of the stretchable flexible substrate depicted in FIG. 10C;

FIG. 10E is a drawing depicting another example of a cross-sectional structure of the stretchable flexible substrate depicted in FIG. 10C;

FIG. 11A is a cross-sectional drawing schematically depicting a third modified example of a stretchable flexible substrate according to an embodiment;

FIG. 11B is a cross-sectional drawing schematically depicting a fourth modified example of a stretchable flexible substrate according to an embodiment;

FIG. 11C is a cross-sectional drawing schematically depicting a fifth modified example of a stretchable flexible substrate according to an embodiment; and

FIG. 11D is a cross-sectional drawing schematically depicting a sixth modified example of a stretchable flexible substrate according to an embodiment.

### DETAILED DESCRIPTION

First, the circumstances that led to the present inventors devising the stretchable flexible substrate of the present disclosure will be described. The present inventors discovered the following four problems.

(1) With a conventional flexible substrate, stretching in the direction of extension of the flexible substrate is possible but stretching in a direction that is different from the direction of extension is difficult. Thus, it is difficult for sufficient stretchability of a level that meets market needs to be exhibited.

(2) With a conventional flexible substrate, it is difficult to ensure high stretchability and also to prevent a breakage in wiring caused by lengthening.

(3) With a conventional woven material into which an electrically conductive thread has been woven, it is difficult to ensure the stability of wiring resistance.

(4) With a conventional woven material into which an electrically conductive thread has been woven, it is difficult to ensure reliability in the mounting of electronic components.

The above mentioned point (2) will be described in detail. A conventional flexible substrate is provided with wiring that has curved sections. For example, in the case where a flexible substrate is attached to a movable part of a human body or a robot arm, the substrate extends in accordance with movement such as bending or extending of the movable part. However, when the amount of extension of the substrate exceeds a fixed level, the curved sections of the wiring extend, and there is a risk of a breakage occurring in a portion of the wiring where stress is likely to concentrate. Increasing the width of the wiring is feasible in order to avoid this problem. Thus, the cross-sectional area of a cross section that intersects the tensile direction increases, and the strength of the wiring increases. However, when the width of a wiring is increased, the space for the curving of the wiring is reduced, and sufficient stretchability can no longer be obtained.

The above mentioned point (3) will be described in detail. A woven material into which an electrically conductive thread has been woven in order to impart a high degree of stretchability is proposed in Japanese Unexamined Patent Application Publication No. 2013-147767. In this woven material, the electrically conductive thread functions as wiring. However, wiring implemented by means of an electrically conductive thread exhibits a higher resistance value than typical metal wiring and large changes in wiring resistance when stretched. These tendencies become notable as the wiring lengthens. Therefore, this woven material is unsuitable for devices for large current applications, such as an LED matrix.

The above mentioned point (4) will be described in detail. With a woven material into which an electrically conductive thread has been woven, flatness is inferior compared to a typical flexible substrate. It is therefore difficult for electronic components to be arranged with high density on this woven material. Furthermore, a woven material has inferior heat resistance compared to a typical flexible substrate. Therefore, mounting methods that require high heat such as solder mounting cannot be applied to this woven material. Consequently, with a woven material into which an electrically conductive thread has been woven, the mounting method is restricted, and it is difficult for a high degree of mounting reliability to be obtained.

The present inventors carried out a diligent investigation in order to solve the aforementioned problems, which thereby led to the present inventors devising a stretchable flexible substrate in which non-stretchable portions of a wiring layer and a stretchable base material are sewed using fiber threads.

In this stretchable flexible substrate, the wiring layer has non-stretchable portions and stretchable strips connected to the non-stretchable portions. The wiring layer has stretchability due to the stretchable strips extending and contracting. In the case where the wiring layer is provided with a flat sheet-like electrically conductive layer, for example, this electrically conductive layer exhibits low wiring resistance and also small changes in wiring resistance when stretched compared to an electrically conductive thread. Furthermore, with this kind of electrically conductive layer, the wiring layer has comparatively high heat resistance. In the case where the non-stretchable portions have a flat-sheet shape, it is easy for electronic components to be arranged. In addition, the wiring layer and the base material are sewed together using fiber threads, and therefore the wiring layer is able to move to an extent on the base material. Therefore, the sewing together of the wiring layer and the base material practically does not inhibit the extension and contraction of the stretchable strips.

Hereinafter, a stretchable flexible substrate according to an embodiment will be described. The various kinds of elements depicted in the drawings are merely depicted in a schematic manner to aid understanding of the present disclosure, and the dimension ratios, the appearance, and the like may be different from actual elements.

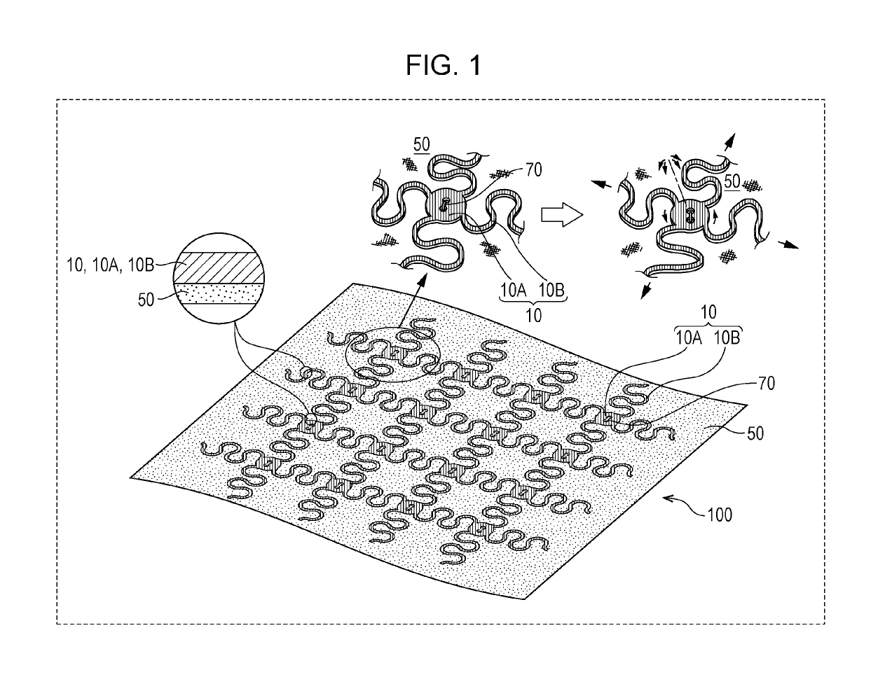

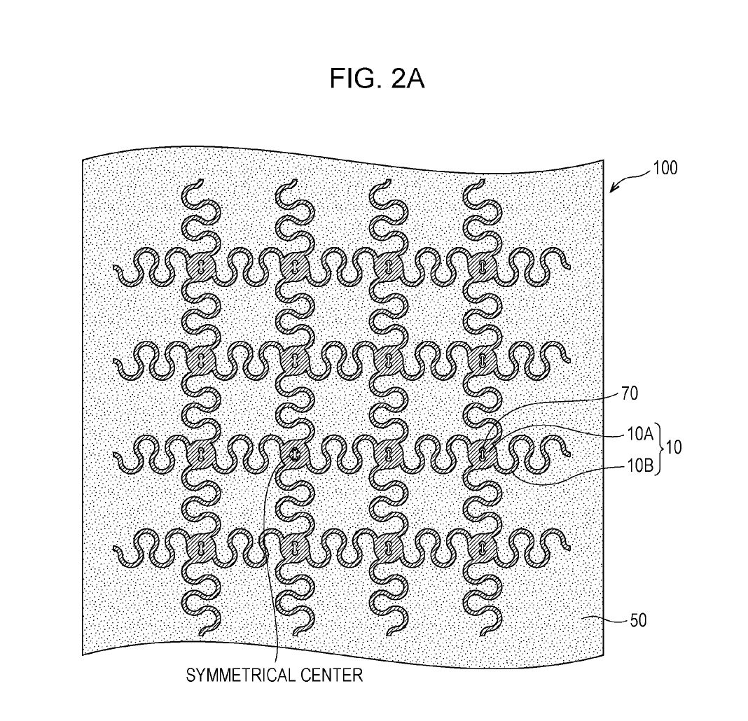

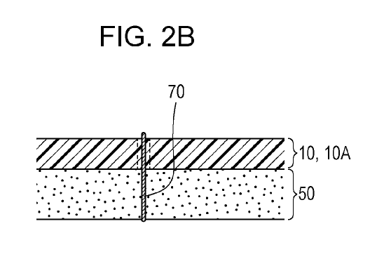

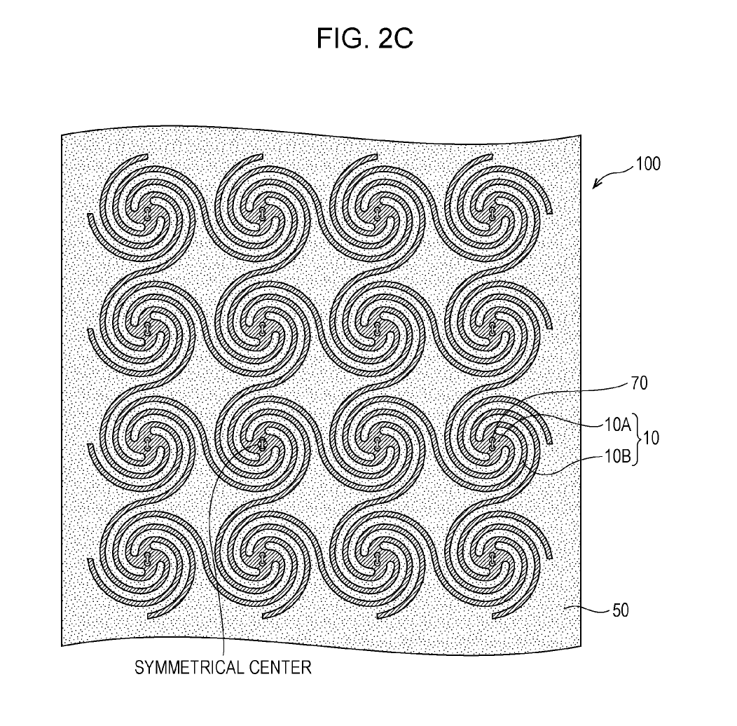

As depicted in FIGS. 1 and 2A to 2C, a stretchable flexible substrate 100 according to an embodiment has a wiring layer 10 and a base material 50. The wiring layer 10 has electrically conductive wiring. The wiring layer 10 includes non-stretchable portions 10A and stretchable strips 10B connected to the non-stretchable portions 10A. The stretchable strips 10B have a shape that is capable of stretching, and the wiring layer 10 is thereby able to stretch. It is desirable for the non-stretchable portions 10A and the stretchable strips 10B to be connected in an integral manner or a continuous manner, for example. That is, it is desirable for the non-stretchable portions 10A and the stretchable strips 10B to be integrated without joints.

The base material 50 in the present embodiment is an example of a “sheet” in the present disclosure. The non-stretchable portions 10A in the present embodiment are an example of a “non-stretchable member” in the present disclosure. The stretchable strips 10B in the present embodiment are an example of a “strip” in the present disclosure.

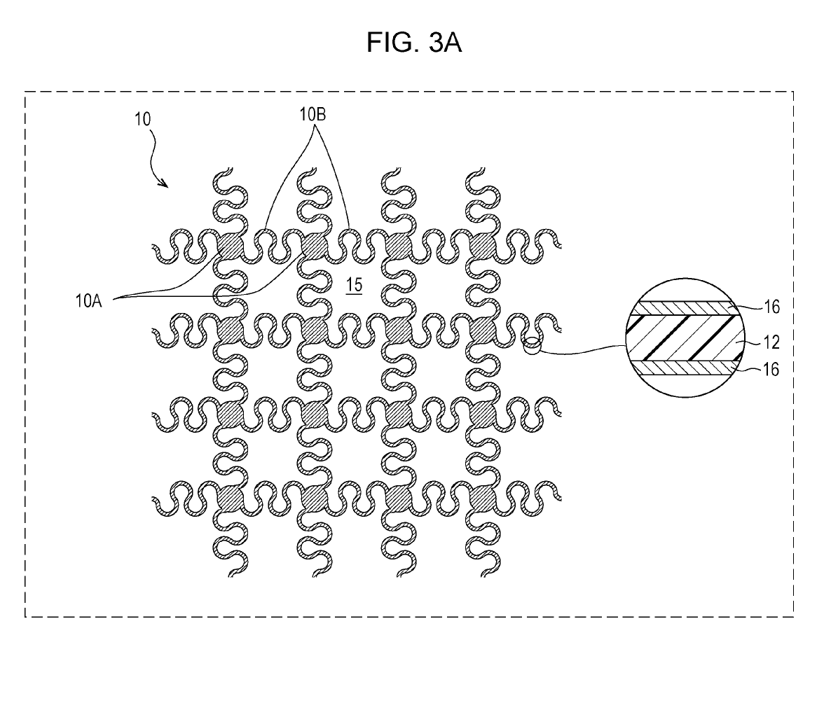

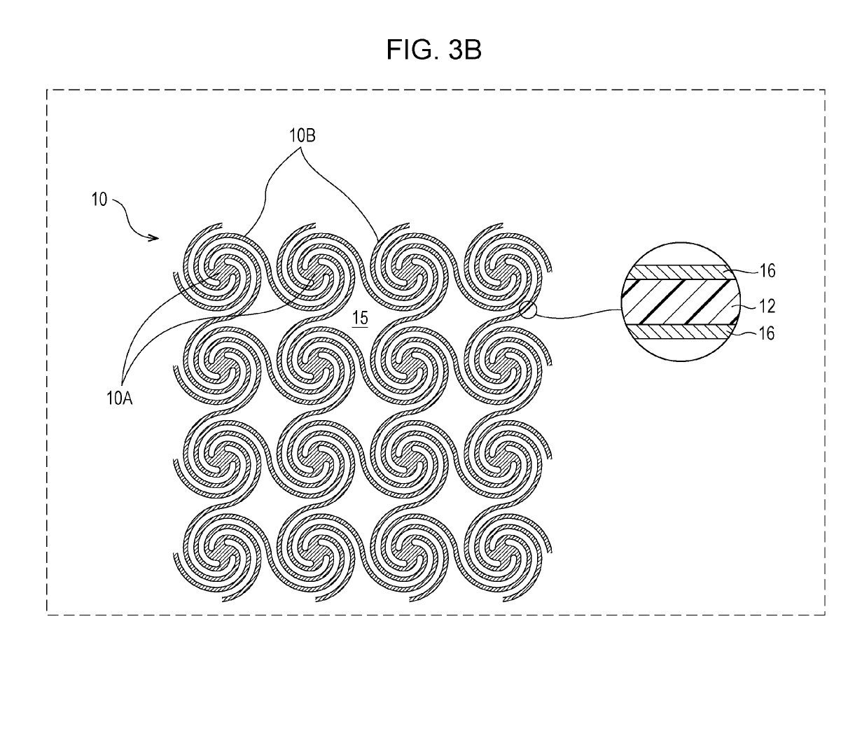

FIGS. 3A and 3B depict only the wiring layer 10. A depicted in the drawings, in the wiring layer 10, a plurality of non-stretchable portions 10A are provided, and adjacent non-stretchable portions 10A are connected to each other by a stretchable strip 10B. The plurality of non-stretchable portions 10A may be arranged in a two-dimensional matrix form, and the stretchable strips 10B may also be arranged in a two-dimensional matrix form in such a way as to connect the non-stretchable portions 10A. It is desirable for the stretchable strips 10B to have curved sections. In this case, the stretchable strips 10B extend and contract due to changes in the curvature of the curved sections, and thus the wiring layer 10 overall exhibits stretchability. Two or more stretchable strips 10B are provided for each non-stretchable portion 10A. It is desirable for the plurality of stretchable strips 10B to be separated from each other by gaps 15. The degree of freedom of the changes in the curvature of the stretchable strips 10B increases as the gaps 15 become larger, thereby facilitating stretching of the stretchable flexible substrate 100 overall. The stretchable flexible substrate 100 deforms and/or stretches in a three-dimensional manner, for example.

The stretchable strips 10B curve in a serpentine shape or a spiral shape, for example. In plan view, the stretchable strips 10B depicted in FIG. 3A have a serpentine shape. In other words, the stretchable strips 10B depicted in FIG. 3A have a meandering shape. Non-stretchable portions 10A that are adjacent to each other are connected by way of a stretchable strip 10B that curves in a serpentine shape therebetween. In plan view, the stretchable strips 10B depicted in FIG. 3B are coiled in spirals. Non-stretchable portions 10A that are adjacent to each other are connected by way of a stretchable strip 10B that curves in a spiral shape therebetween.

In the case where a plurality of non-stretchable portions 10A are arranged with a predetermined pitch, a wiring layer 10 that has spiral-shaped stretchable strips 10B is able to extend to a greater extent than a wiring layer 10 that has serpentine-shaped stretchable strips 10B. This is due to the following two reasons.

(1) The curved sections of a spiral-shaped stretchable strip 10B curve with a greater radius of curvature than the curved sections of a serpentine-shaped stretchable strip 10B. It is thereby possible to obtain a greater allowance in length for the stretchable strips 10B.

(2) A spiral-shaped stretchable strip 10B displaces in such a way that the spirals loosen, and therefore this displacement assists the extension of the stretchable strip.

Furthermore, a wiring layer 10 that has spiral-shaped stretchable strips 10B is able to be extended by means of a smaller tensile force than a wiring layer 10 that has serpentine-shaped stretchable strips 10B.

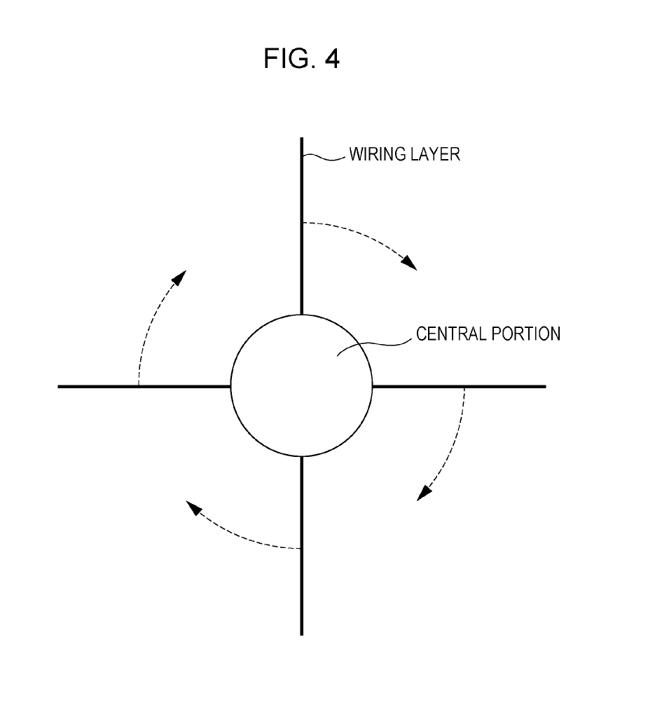

For example, as depicted in FIG. 4, spiral-shaped stretchable strips 10B are obtained by wiring that extends from a central portion (a non-stretchable portion 10A, for example) being made to curve in a clockwise direction as indicated by the dashed arrows. The curvature of the spiral-shaped stretchable strips 10B decreases as the stretchable flexible substrate 100 extends. Thus, the stretchable strips 10B deform in such a way as to move away from the outer periphery of a non-stretchable portion 10A, from the one end connected to the non-stretchable portion 10A toward the other end.

As depicted in FIG. 4, a plurality of spiral-shaped stretchable strips 10B connected to one non-stretchable portion 10A all curve along the outer periphery of that non-stretchable portion 10A. Therefore, it is possible to decrease the margin between the stretchable strips 10B, and it is possible to increase the housability of the stretchable strips 10B and the wiring formed thereon. For example, in the case where sections that include a non-stretchable portion 10A and a plurality of spiral-shaped stretchable strips 10B are arranged in a matrix form, it is possible for the stretchability of the stretchable strips 10B and the housability of the wiring thereon to be increased.

The spiral-shaped stretchable strips 10B desirably extend along at least half of a perimeter of a non-stretchable portion 10A. For example, the spiral-shaped stretchable strips 10B may extend along a perimeter of a non-stretchable portion 10A one or more times, or may extend along a perimeter of a non-stretchable portion 10A three or more times. It should be noted that the shape of the non-stretchable portions 10A is not particularly restricted. The shape of the non-stretchable portions 10A may be a circle or an ellipse, or may be a polygon such as a quadrilateral or a hexagon. The curved sections of the stretchable strips 10B may be curved in a curved line shape, or may be bent in an angular manner.

The wiring layer 10 includes electrically conductive wiring. For example, as depicted in the partial cross-sectional views in FIGS. 3A and 3B, the wiring layer 10 includes an insulating base material 12 and electrically conductive wiring 16. The electrically conductive wiring 16 is provided on the main surfaces of the insulating base material 12, for example. In other words, the insulating base material 12 and the electrically conductive wiring 16 are layered on each another. In the case where the electrically conductive wiring 16 has bent sections, it is possible to increase the length of the electrically conductive wiring 16 that can be housed per unit area.

The insulating base material 12 has an electrical insulating property. It is desirable for the insulating base material to have a sheet shape. It is desirable for the insulating base material 12 to be flexible. The material for the insulating base material 12 may be a resin material. A possible example of the material for the insulating base material 12 is at least one type of material selected from the group consisting of an acrylic resin, a urethane resin, a silicone resin, a fluororesin, a polyimide resin, an epoxy resin, and the like.

The electrically conductive wiring 16 is electrically conductive. The electrically conductive wiring 16 may be in the form of a thin film. It is desirable for the electrically conductive wiring 16 to contain a metal material. A possible example of a metal material for the electrically conductive wiring 16 is at least one type selected from the group consisting of gold (Au), silver (Ag), copper (Cu), nickel (Ni), chromium (Cr), cobalt (Co), magnesium (Mg), calcium (Ca), platinum (Pt), molybdenum (Mo), iron (Fe), and zinc (Zn). The thickness of the electrically conductive wiring 16, for example, may be of the order of 5 μm to 1000 μm, desirably of the order of 5 μm to 500 μm, and more desirably of the order of 5 μm to 250 μm. The electrically conductive wiring 16 may be a layer formed from metal foil. In this case, the metal foil may be subjected to patterning processing, for example.

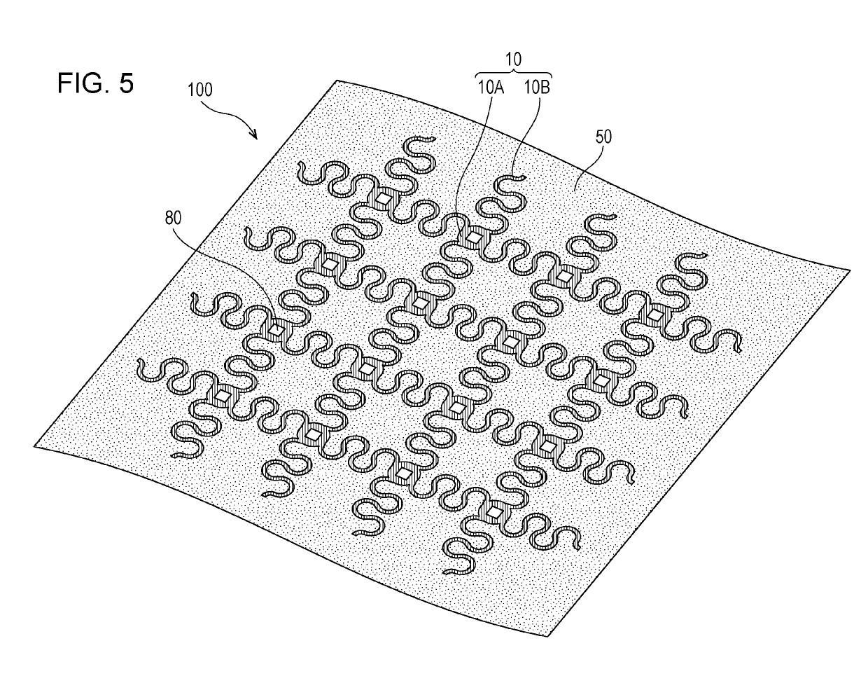

For example, as depicted in FIG. 5, electronic components 80 may be provided on the wiring layer 10. The electronic components 80 are electrically connected to the wiring layer 10 (for example, the electrically conductive wiring 16). It is desirable for the electronic components 80 to be provided on the non-stretchable portions 10A of the wiring layer 10, as depicted in FIG. 5. The electronic components 80 are less affected by the stretching of the stretchable flexible substrate 100. The electronic components 80 may be various electronic components used in the electronic mounting field, and are not particularly restricted. Possible examples of the electronic components 80 are a semiconductor element, a temperature sensor, a pressure sensor, an actuator, and the like. A semiconductor element is a light-emitting element, a light-receiving element, a diode, or a transistor, for example. Other possible examples of the electronic components 80 are an IC (a control IC, for example), an inductor, a capacitor, a power element, a chip resistor, a chip capacitor, a chip varistor, a chip thermistor, another chip-shaped laminated filter, a connection terminal, and the like. A plurality of types of electronic components 80 may be provided on the stretchable flexible substrate 100.

The manufacturer may mount the electronic components 80 on the non-stretchable portions 10A of the wiring layer 10, and thereafter sew the wiring layer 10 onto the base material 50. A mounting method requiring high heat may be adopted in order to mount the electronic components 80 on the wiring layer 10.

The base material 50 supports the wiring layer 10, for example. The base material 50 has an insulating property, for example. The base material 50 is provided in such a way as make contact with the wiring layer 10 in a direct or indirect manner. The wiring layer 10 and the base material 50 may be layered on each another, as depicted in FIGS. 1 and 2B. A main surface of the wiring layer 10 and a main surface of the base material 50 face each other. A main surface of the wiring layer 10 is a surface that extends in the direction in which the non-stretchable portions 10A and the stretchable strips 10B are arranged.

The base material 50 is a flexible sheet, for example. The stretchable flexible substrate 100 is thereby able to be flexible. The base material 50 may also be stretchable. The stretchable flexible substrate 100 is thereby able to be stretchable. The base material 50 may be a resin material (an elastomer material, for example), or a fiber fabric, for example. The base material 50 may be air-permeable and/or light-permeable.

The wiring layer 10 and the base material 50 are sewed together by means of a fiber thread 70, as depicted in FIGS. 1 and 2A to 2C. The fiber thread 70 can attach the wiring layer 10 to the base material 50 without greatly inhibiting the extension and contraction of the wiring layer 10. There are no particular restrictions regarding the way in which the sewing is carried out by means of the fiber thread 70. For example, a method that is used when attaching a button to clothing by a thread may be adopted as the way in which the sewing is carried out. The wiring layer 10 and the base material 50 may be attached only by the fiber thread 70. The locations of attachment by the fiber thread 70 are scattered, thereby ensuring the flexible stretchability of the stretchable flexible substrate 100.

The fiber thread 70 may be a fiber itself, or may be a thread obtained by processing a fiber. It is desirable for the fiber thread 70 to be flexible. The fiber included in the fiber thread 70 may be a short fiber or a long fiber, or may be a hollow fiber. The fiber thread 70 may be a twisted thread. In this case, the fiber thread 70 is able to have high strength.

Although the non-stretchable portions 10A are attached to the base material 50 by way of the fiber thread 70, for example, it may be possible for the non-stretchable portions 10A to rotate and/or displace with respect to the base material 50. This can be realized by the non-stretchable portions 10A and the base material 50 being sewed loosely with the fiber thread 70, for example. Alternatively, this can be realized by the fiber thread 70 having elasticity.

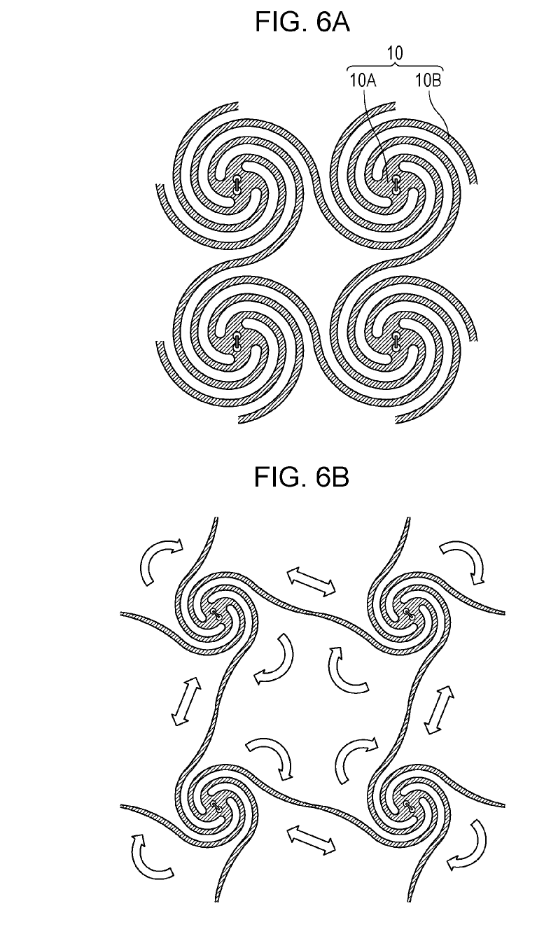

For example, when the wiring layer 10 stretches, the non-stretchable portions 10A may rotate about the locations where attached by the fiber thread 70, as depicted in FIGS. 6A and 6B. Thus, it is possible to release some of the stress applied to the non-stretchable portions 10A, and it is possible to improve the degree of freedom of the stretching of the stretchable flexible substrate 100.

For example, when the wiring layer 10 stretches, the non-stretchable portions 10A may displace in a predetermined direction with respect to the base material 50. For example, a design may be implemented in such a way that, when viewed from a direction perpendicular to a main surface of a non-stretchable portion 10A, it is possible for the location where the fiber thread 70 passes through the non-stretchable portion 10A and the location where the fiber thread 70 passes through the base material 50 to deviate. Thus, it is possible to release some of the stress applied to the non-stretchable portions 10A, and it is possible to improve the degree of freedom of the stretching of the stretchable flexible substrate 100.

The fiber thread 70 may sew the centers of the non-stretchable portions 10A and the base material 50 together. When a plurality of stretchable strips 10B connected to a non-stretchable portion 10A stretch, the non-stretchable portion 10A may rotate about the fiber thread 70. In other words, a plurality of stretchable strips 10B connected to a certain non-stretchable portion 10A may be arranged in a rotationally symmetrical manner about the fiber thread 70 attached to that non-stretchable portion 10A. The rotational symmetry may be point symmetry, for example. Thus, when a rotational force is applied to the non-stretchable portion 10A due to the plurality of stretchable strips 10B stretching, for example, the non-stretchable portion 10A rotates, and stress can thereby be efficiently released. As a result, it is possible to improve the degree of freedom of the stretching of the stretchable flexible substrate 100. Here, the “center” is not restricted to the exact center. For example, when viewed from a direction perpendicular to a main surface of a non-stretchable portion 10A, in the case where the fiber thread 70 is arranged in such a way as be applied in a predetermined region of the non-stretchable portion 10A, this predetermined region corresponds to the “center”.

The “plurality of stretchable strips 10B being arranged in a rotationally symmetrical manner” is not restricted to strict rotational symmetry. For example, in the case where the shape of the non-stretchable portions 10A does not have rotational symmetry, the plurality of stretchable strips 10B may have rotational symmetry excluding the sections connecting with the non-stretchable portions 10A.

The fiber thread 70 may be electrically conductive. For example, an electrically conductive member on the front surface of the wiring layer 10 and an electrically conductive member on the rear surface may be electrically connected by way of the fiber thread 70. Alternatively, an electrically conductive member within the wiring layer 10 and an electrically conductive member within the base material 50 may be electrically connected by way of the fiber thread 70. Since a fiber thread 70 that is electrically conductive is a comparatively light conductor, the stretchable flexible substrate 100 can therefore be made lighter. Furthermore, with a fiber thread 70 that is electrically conductive, it is possible for electric resistance to be adjusted in a comparatively simple manner by changing, as appropriate, the way in which sewing is carried out (for example, the number of turns of the thread) or the like.

A fiber thread that is electrically conductive may be, for example, a metal fiber, a coated fiber, an electrically conductive polymer fiber, or a thread that has been formed, configured, or processed from these. For example, a metal fiber may include at least one type of metal selected from the group consisting of gold (Au), silver (Ag), copper (Cu), nickel (Ni), chromium (Cr), cobalt (Co), magnesium (Mg), calcium (Ca), platinum (Pt), molybdenum (Mo), iron (Fe), and zinc (Zn). A coated fiber may be formed by coating a thread or fiber that includes at least one of a polymer, carbon, and cotton with the above mentioned metal. An electrically conductive polymer fiber may be polyacetylene, polyparaphenylene, polyaniline, polythiophene, polyparaphenylene vinylene, and/or polypyrrole, for example.

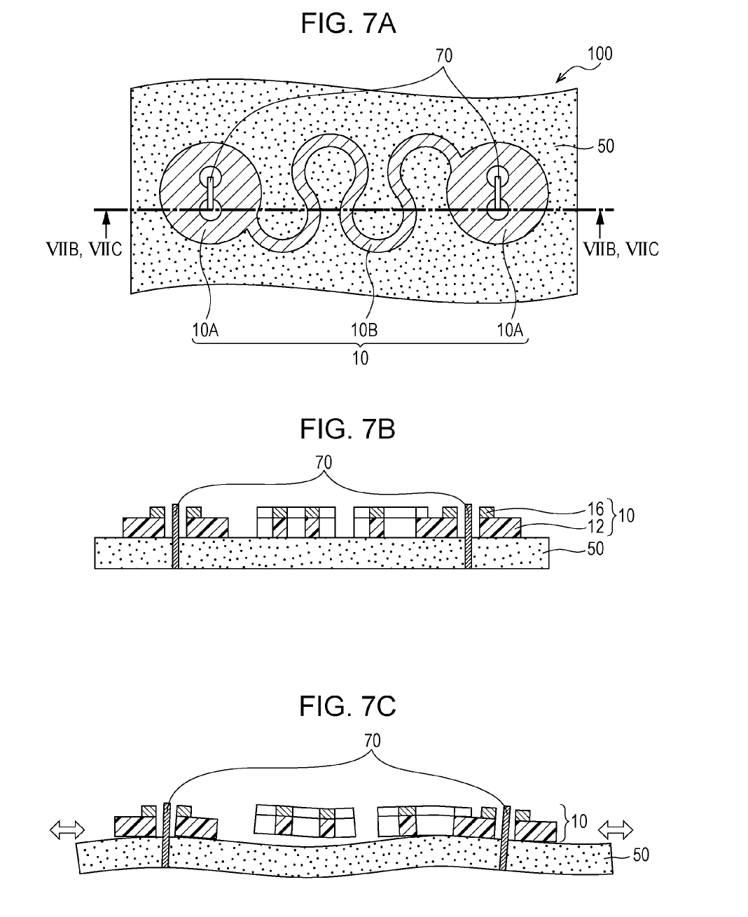

One exemplary configuration of the stretchable flexible substrate 100 will be described in detail. FIG. 7A schematically depicts a stretchable flexible substrate 100 provided with a wiring layer 10 that includes curved stretchable strips 10B, and a base material 50 configured from a fiber fabric. FIGS. 7B and 7C depict cross sections along VIIB and VIIC in FIG. 7A. FIG. 7B is a cross-sectional drawing of when the stretchable flexible substrate 100 is not extended. FIG. 7C is a cross-sectional drawing of when the stretchable flexible substrate 100 is extended.

In the wiring layer 10, a plurality of non-stretchable portions 10A are arranged in a two-dimensional matrix form, and a plurality of stretchable strips 10B link the non-stretchable portions 10A. In other words, the non-stretchable portions 10A are arranged in positions corresponding to intersecting points of the plurality of stretchable strips 10B. The plurality of non-stretchable portions 10A are scattered in an island-like manner. Electronic components 80 may be mounted on the non-stretchable portions 10A. The plurality of stretchable strips 10B curve in a serpentine shape between the non-stretchable portions 10A.

As depicted in FIG. 7B, the wiring layer 10 includes an insulating base material 12 and electrically conductive wiring 16, and these are layered on each another. A polyimide film may be used as the insulating base material 12, and pattern-formed copper foil may be used as the electrically conductive wiring 16, for example. The fiber thread 70 may sew the non-stretchable portions 10A of the wiring layer 10 and the base material 50 together.

When an external tensile force is applied to the stretchable flexible substrate 100, the stretchable strips 10B of the wiring layer 10 extend and bend, thereby causing the stretchable flexible substrate 100 to stretch, as depicted in FIG. 7C. At such time, if the base material 50 is a fiber fabric, plastic deformation of the wiring layer 10 is prevented by the elastic force (in other words, the reaction force) of the fiber fabric. As a result, a breakage or disconnection of the wiring layer 10 can be prevented.

The base material 50 is a fiber fabric, for example. The fiber fabric is made of a chemical fiber and/or a natural fiber.

The chemical fiber may be a synthetic fiber, a semisynthetic fiber, a regenerated fiber, and/or an inorganic fiber. Possible examples of the synthetic fiber are an aliphatic polyamide fiber (for example, a nylon 6 fiber and a nylon 66 fiber), an aromatic polyamide fiber, a polyvinyl alcohol fiber (for example, a vinylon fiber), a polyvinylidene chloride fiber, a polyvinyl chloride fiber, a polyester fiber (for example, a polyester fiber, a PET fiber, a PBT fiber, and a polyarylate fiber), a polyacrylonitrile fiber, a polyethylene fiber, a polypropylene fiber, a polyurethane fiber, a phenol fiber, a polyfluoroethylene fiber, and the like. Possible examples of the semisynthetic fiber are a cellulose fiber, a protein fiber, and the like. Possible examples of the regenerated fiber are a rayon fiber, a cupra fiber, a lyocell fiber, and the like. Also, possible examples of the inorganic fiber are a glass fiber, a carbon fiber, a ceramic fiber, a metal fiber, and the like.

The natural fiber may be a plant fiber, an animal fiber, or a mixed fiber thereof. Possible examples of a plant fiber are cotton, hemp (for example, flax and ramie), and the like. Possible examples of an animal fiber are hair (for example, sheep wool, angora, cashmere, and mohair), silk, plumage (for example, down and feathers), and the like.

The fiber itself that is used for the fiber fabric may be a short fiber or a long fiber, or also may be a hollow fiber. Furthermore, the fiber that is used for the fiber fabric may have a thread form, or a twisted thread form in which fibers are intertwined, for example. The fiber, or a thread made of the fiber, may itself have elastic characteristics.

The fiber fabric may be any of a fiber woven material, a fiber knitted material, and a non-woven fabric. That is, the fiber fabric may be a woven material into which so-called warp threads and weft threads have been woven in such a way as to intersect, or may be a mesh material into which threads are woven in such a way as to bend. Alternatively, the fiber fabric may be a non-woven fabric (for example, a needle-punch fabric or a spunbond fabric).

The base material 50 may be a material that deforms when pulled, practically returns to the original shape when deloaded, and when the amount of deformation caused by pulling exceeds a predetermined level, the reaction force (in other words, the elastic force) rapidly increases. Thus, it is possible to prevent the wiring layer 10 coming to plastically deform when the stretchable flexible substrate is extended, and it is possible to prevent a breakage and/or disconnection of the wiring layer 10. This kind of material, for example, is configured from bent fiber threads and is able to flexibly extend due to the bending deformation, and the reaction force (in other words, the elastic force) rapidly increases when the bending is completely extended.

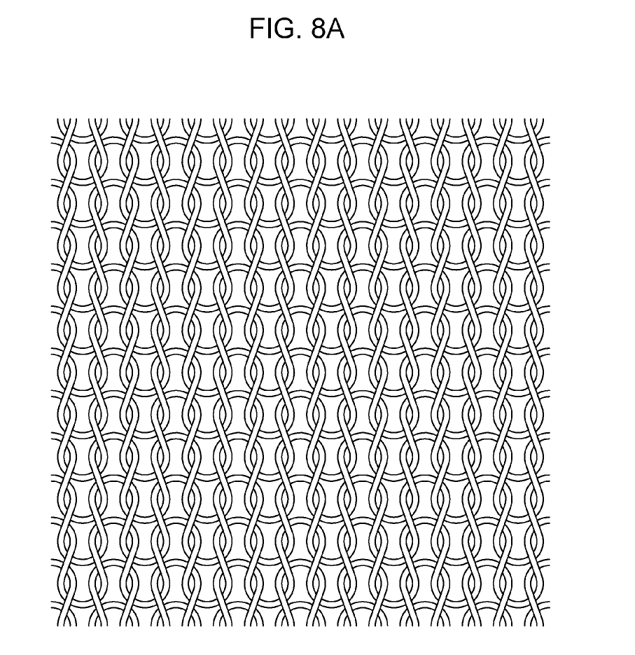

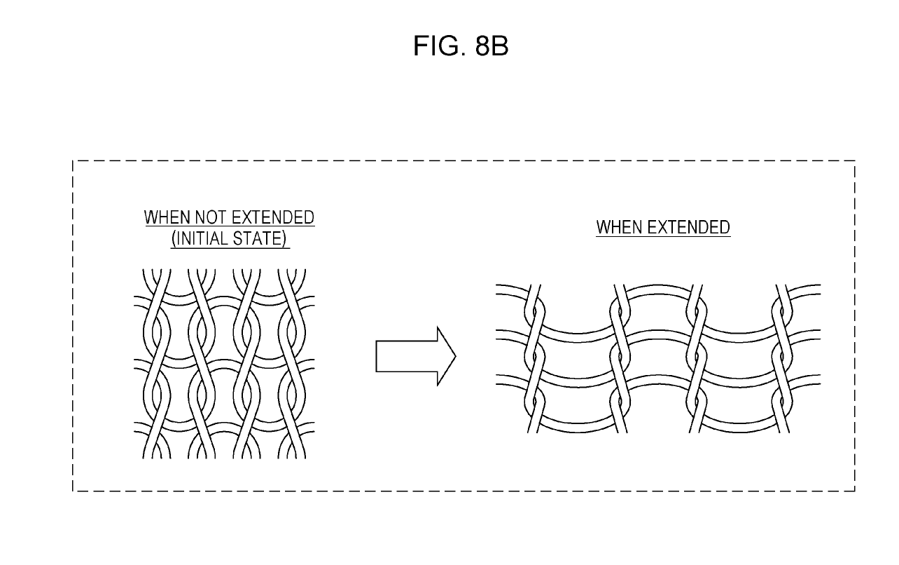

The fiber fabric may have a knitted structure such as that depicted in FIGS. 8A and 8B, for example. A material having a knitted structure is knitted while adjacent fiber threads are entwined together. In a knitted structure, when focusing on a single fiber thread, the fiber thread is entwined with adjacent fiber threads in an alternating manner while forming a serpentine shape as depicted in the drawings. Since the fiber thread has a serpentine shape, an extension allowance with respect to tension is sufficiently ensured. Knitted structures, for example, are used as material for sweaters, jerseys, stockinette stitch shirts, or the like. A material having this kind of knitted structure has abundant flexibility and stretchability in regions in which the amount of extension is comparatively small, and when extension advances and a state is entered in which the fiber threads are more or less completely extended, the reaction force rapidly increases and further extension becomes difficult.

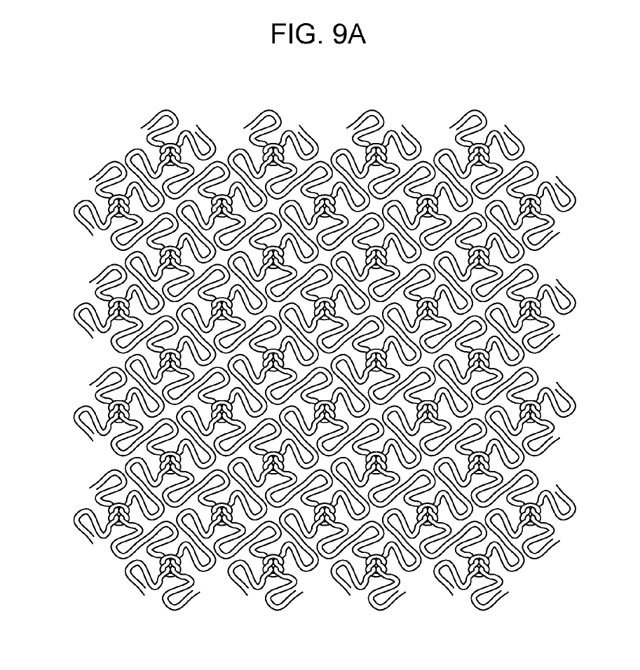

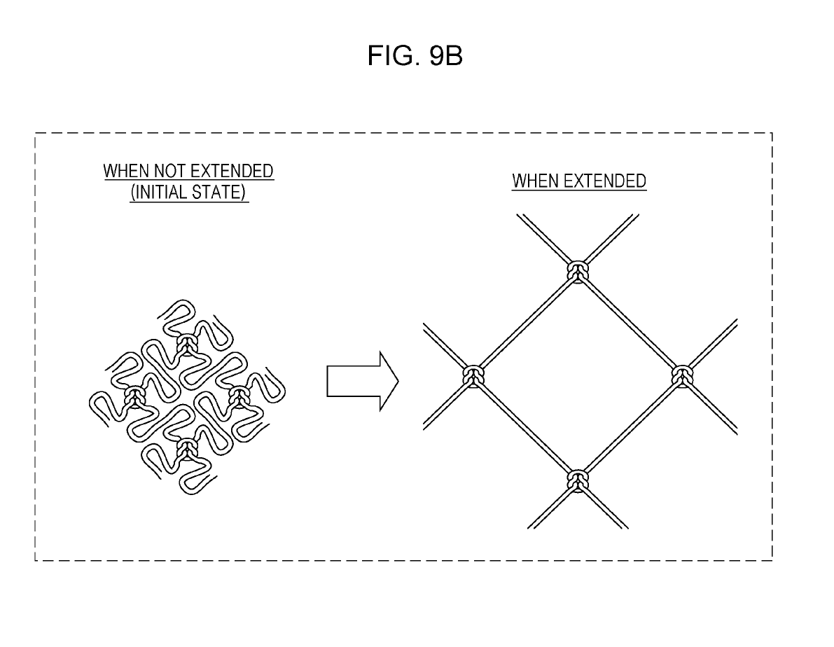

The fiber fabric may have a net structure such as that depicted in FIGS. 9A and 9B, for example. In a material having a net structure, fiber threads are tied at intersecting points to form a lattice shape, and fiber threads linking lattice points form a serpentine shape having allowance. The fiber threads of the net structure have a serpentine shape when not extended, and when completely extended, the reaction force rapidly increases, and further extension becomes difficult.

### MODIFIED EXAMPLES

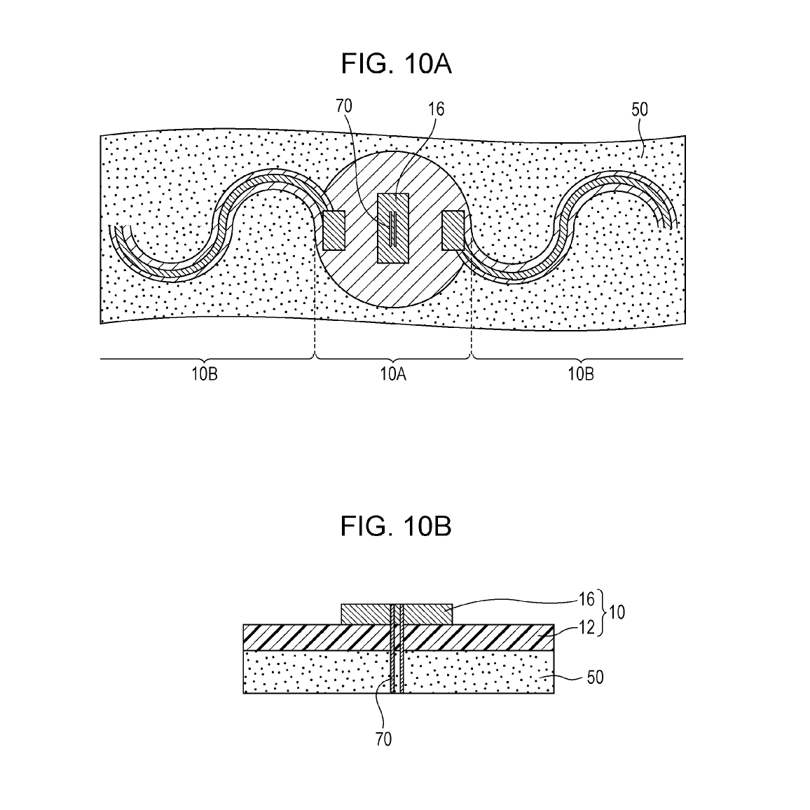

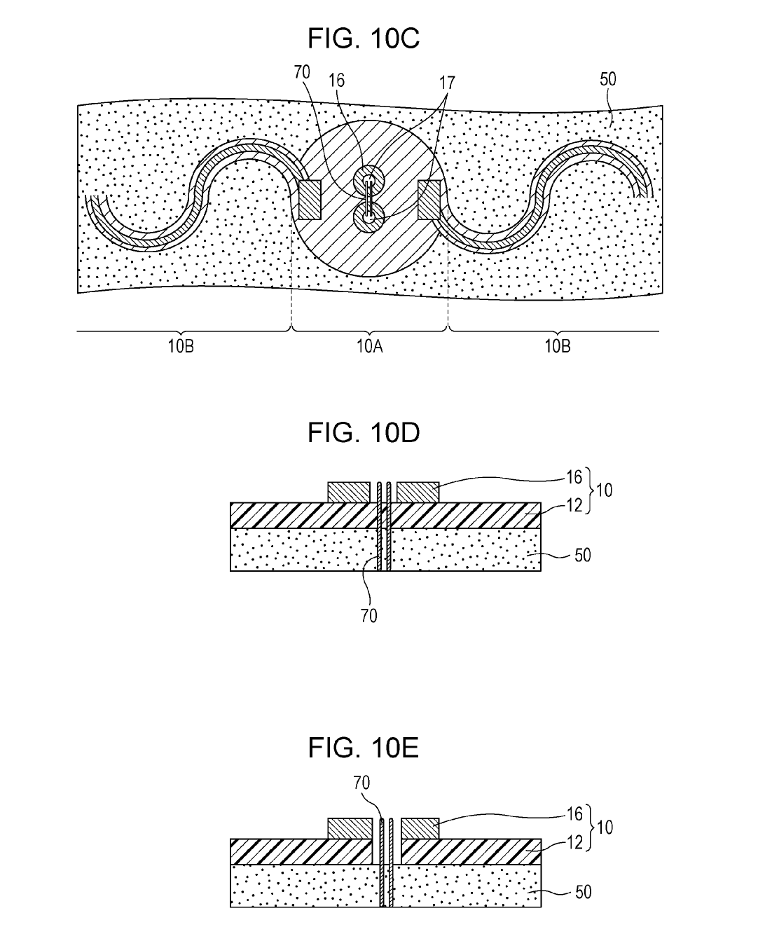

FIG. 10A depicts a first modified example of the stretchable flexible substrate 100, and FIG. 10B depicts a cross section near a non-stretchable portion 10A depicted in FIG. 10A. In the first modified example, the electrically conductive wiring 16 of the non-stretchable portion 10A is constituted by an electrically conductive pad, and the fiber thread 70 passes through this electrically conductive pad. In the case where the electrically conductive pad is formed of a comparatively hard metal, sewing by means of the fiber thread 70 can be easily carried out.

FIG. 10C depicts a second modified example of the stretchable flexible substrate 100, and FIG. 10D depicts a cross section near a non-stretchable portion 10A depicted in FIG. 10C. In the second modified example, an opening 17 that passes through an electrically conductive pad is provided in the non-stretchable portions 10A. The fiber thread 70 passes through this opening 17. The non-stretchable portions 10A are able to displace to a small extent from a predetermined location on the base material 50 in accordance with the size of this opening 17. Thus, it is possible to release some of the stress applied to the non-stretchable portions 10A, and it is possible to improve the degree of freedom of the stretching of the stretchable flexible substrate 100. Furthermore, in the case where the electrically conductive pad is formed of a comparatively hard metal, sewing by means of the fiber thread 70 can be easily carried out. It should be noted that the opening 17 may pass through the entirety of the wiring layer 10, as depicted in FIG. 10E.

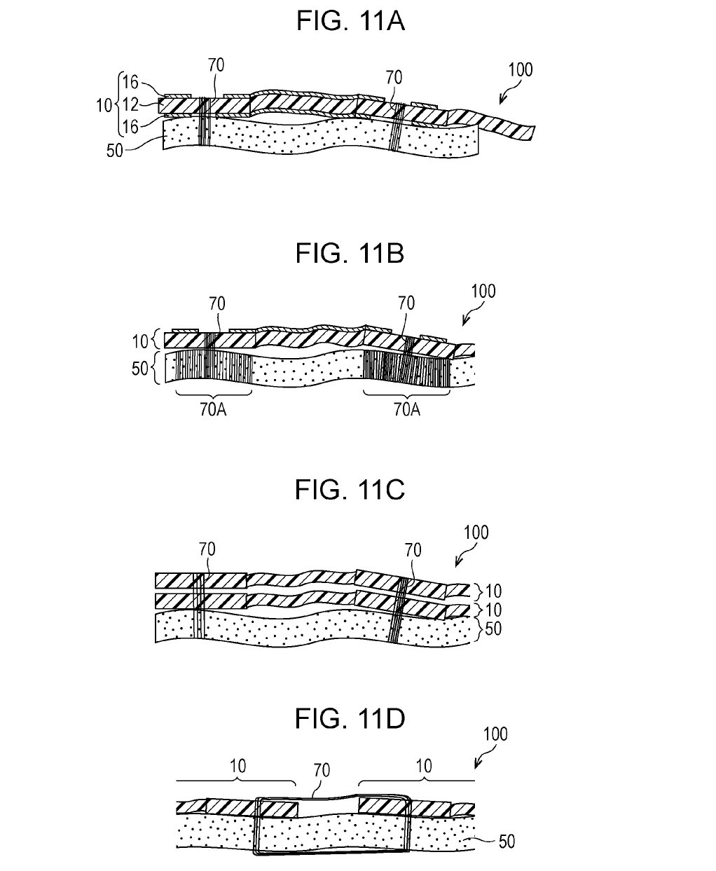

FIG. 11A depicts a third modified example of the stretchable flexible substrate 100. For convenience, FIG. 11A depicts a cross section that passes through the center of the non-stretchable portions 10A and follows a direction in which the stretchable strips 10B extend. In the third modified example, the wiring layer 10 has electrically conductive wiring 16 on both of the front surface side and rear surface side of the insulating base material 12. The degree of freedom of the wiring pattern of the wiring layer 10 thereby increases. In addition, in the case where the fiber thread 70 is electrically conductive, the fiber thread 70 is able to electrically connect the electrically conductive wiring 16 on the front surface side and the electrically conductive wiring 16 on the rear surface side.

FIG. 11B depicts a fourth modified example of the stretchable flexible substrate 100. For convenience, FIG. 11B depicts a cross section that passes through the center of the non-stretchable portions 10A and follows a direction in which the stretchable strips 10B extend. In the fourth modified example, a fiber thread 70 that is electrically conductive is wound around the base material 50, and a portion of this wound fiber thread 70 that is exposed on the rear surface of the base material 50 functions as a rear surface electrode 70A. The degree of design freedom of the stretchable flexible substrate 100 thereby increases.

FIG. 11C depicts a fifth modified example of the stretchable flexible substrate 100. For convenience, FIG. 11C depicts a cross section that passes through the center of the non-stretchable portions 10A and follows a direction in which the stretchable strips 10B extend. In the fifth modified example, a plurality of the wiring layers 10 are layered on the base material 50, and the plurality of wiring layers 10 are sewed to the base material 50 by the fiber thread 70 passing therethrough. Thus, the circuit density per unit area can be increased, and the degree of design freedom of the stretchable flexible substrate 100 increases.

FIG. 11D depicts a sixth modified example of the stretchable flexible substrate 100. For convenience, FIG. 11D depicts a cross section that passes through the center of the non-stretchable portions 10A and follows a direction in which the stretchable strips 10B extend. In the sixth modified example, a fiber thread 70 that is electrically conductive passes through a plurality of separated adjacent wiring layers 10, and sews the wiring layers 10 and the base material 50 together. Thus, the fiber thread 70 electrically connects the plurality of separated adjacent wiring layers 10.

The present disclosure is not restricted to a specific example described in the above mentioned embodiment or modified examples thereof, and also includes modes in which an alteration, substitution, addition, omission, combination, or the like has been implemented thereto as appropriate.

A stretchable flexible substrate of the present disclosure is able to be used in the field of electronic devices, the field of wearable devices, the health care field, the medical field, and the nursing field.

What is claimed is:

1. A substrate, comprising:
a stretchable sheet;
a plurality of members located on the sheet;
a plurality of strips that are stretchable, and that connect the plurality of members; and
a plurality of fiber threads that sew the plurality of members and the sheet together.

2. The substrate according to claim 1,
wherein the plurality of members include a first member, the plurality of strips include a plurality of first strips that are connected to the first member,
the plurality of fiber threads include a first fiber thread that sews the first member and the sheet together, and
the plurality of first strips are disposed in a rotationally symmetrical manner about the first fiber thread.

3. The substrate according to claim 1,
wherein the plurality of members include a first member,
the plurality of strips include a plurality of first strips that are connected to the first member,
the plurality of fiber threads include a first fiber thread that sews the first member and the sheet together, and
the first member is allowed to rotate about the first fiber thread when the plurality of first strips stretch.

4. The substrate according to claim 2,
wherein the first fiber thread, when viewed from a direction perpendicular to a main surface of the first member, allows a location where the first fiber thread passes through the first member to deviate from a location where the first fiber thread passes through the sheet.

5. The substrate according to claim 1,
wherein each of the plurality of fiber threads is stretchable.

6. The substrate according to claim 1,
wherein each of the plurality of fiber threads is electrically conductive.

7. The substrate according to claim 1,
wherein each of the plurality of fiber threads is a twisted thread.

8. The substrate according to claim 1,
wherein each of the plurality of strips is curved.

9. The substrate according to claim 8,
wherein each of the plurality of strips has a serpentine shape.

10. The substrate according to claim 8,
wherein each of the plurality of first strips has a spiral shape that extends along at least half of a perimeter of the first member.

11. The substrate according to claim 1,
wherein each of the plurality of members is a flat sheet that includes an electrically conductive layer.

12. The substrate according to claim 11,
wherein each of the plurality of fiber threads is electrically conductive,
and each of the plurality of fiber threads passes through one corresponding electrically conductive layer of the plurality of members.

13. The substrate according to claim 1,
wherein each of the plurality of strips includes electrically conductive wiring.

14. The substrate according to claim 13,
wherein each of the plurality of strips further includes an insulating member.

15. The substrate according to claim 1,
wherein the sheet includes a fiber fabric.

16. The substrate according to claim 15,
wherein the fiber fabric has a knitted structure.

17. The substrate according to claim 15,
wherein the fiber fabric has a net structure.

18. The substrate according to claim 15,
wherein the fiber fabric further includes an elastomer.

19. The substrate according to claim 1, further comprising:
at least one electronic component each located on at least one of the plurality of members.

20. The flexible substrate according to claim 1, wherein the members are non-stretchable members.
